(19) United States
(12) Patent Application Publication
(10) Pub. No.: US 2026/0340231 A1
(43) Pub. Date: Oct. 29, 2026

(54) System and Method for Data Processing Optimization

(71) Applicant: Bank of America Corporation, Charlotte, NC (US)

(72) Inventors: Pratap Dande, Saint Johns, FL (US); Jayabalaji Murugan, Chennai (IN); Varun Easwarchandran, Davidson, NC (US); Gilberto Regis dos Santos, Jacksonville, FL (US)

(21) Appl. No.: 19/193,569

(22) Filed: Apr. 29, 2025

(51) Int. Cl. G06F 30/27

(52) U.S. Cl. CPC G06F 30/27

(57) ABSTRACT

A system and method for optimizing a monitored system using artificial intelligence to detect optimization issues and automatically perform actions to correct them. The system includes a processor that receives the current performance metrics that include information related to key performance indicators (KPIs) associated with a monitored system. The processor extracts a plurality of predetermined features from the current performance metrics and produces an optimization value by analyzing the extracted features using a trained artificial intelligence model that was trained using the historical performance metrics. When the optimization value is greater than a threshold, the processor analyzes the current performance metrics to identify specific optimization issues and determine an action to correct the specific issue. The processor then causes the monitored system to perform the action and stores the current performance metrics, the specific issue, and the action in a log.

### TECHNICAL FIELD

The present disclosure generally relates to distributed computing and, more specifically, to a system and method for data processing optimization.

### BACKGROUND

Large organizations often utilize complex computing systems, such as data centers, to carry out day-to-day operations. Many applications and computing devices in these systems may be connected by local connections and/or broader networks such as the Internet. The applications are increasingly interdependent upon each other and the computing devices hosting them. When functioning normally, these large complex computing systems provide increased efficiencies and survivability.

### SUMMARY

Organizations increasingly use large, complex computing systems to store data and perform various operations needed for their day-to-day activities. These complex computing systems may include multiple servers, computational devices, databases, and storage components. The computing systems may also host multiple applications that work with each other and access data stored in the databases. Additionally, the applications and servers that host them may be geographically dispersed and/or partially or entirely hosted on cloud or edge servers.

With all of this complexity, it may be difficult or impossible for an organization to completely understand the organization's own computing systems. Because of the complexity, the systems become inefficient over time as small anomalies, inefficiencies, or issues may occur that, due to the interconnected nature of the computing systems, have the potential to cause system-wide problems. The issues may be such things as, but not limited to, lack of computing capacity, insufficient distribution of available computing capacity, applications that have not been updated, corrupt data, hardware issues, attacks by bad actors, network issues, and other issues with a monitored system. The resulting inefficiencies may result in more computing being needed than necessary, using greater electrical resources, and requiring more expensive computing equipment. Over time, these inefficiencies and/or issues may also result in system failures and costly downtime when actions are not taken to correct the issues and/or improve the optimization of the monitored system.

Because of the complexity, a single operator or administrator is unable to understand and monitor all of the interconnected systems and applications. Currently, at best, each computational device, application, and database may have its own system administrators or automated applications for monitoring them, but since each system may affect one or more other systems or applications, this may not be sufficient. As systems are upgraded or changed, the other system and the administrators of the other systems may not be aware of the upgrades or changes, resulting in additional unintended inefficiencies and issues. Because the monitoring is compartmentalized, a change to a monitored system that is innocuous for that system may reduce the efficiencies of the communication network and/or a connected system. For example, in a non-limiting example, if a database is updated to store data in a different manner, but an application accessing it is not upgraded, the accessing application may no longer be using the most efficient technique to access the data, or the application may simply fail. Currently, there is no monitoring system that understands multiple connected systems, adapts to changes in constituent systems, and takes appropriate actions automatically and in real-time or near real-time to identify when a monitored system has become inefficient and take actions to optimize the monitored system prior to the inefficiencies causing noticeable slowing and/or catastrophic failures.

The system and method disclosed in the present application provide a technical solution to the technical problems discussed above by monitoring real-time or near real-time performance metrics received from monitored systems and using artificial intelligence to identify issues that cause the monitored systems to be inefficient and require optimization. Further, the system and method perform automated actions to correct the identified issues and provide information on the issues and actions to users or administrators so that they may understand ongoing trends and provide feedback for updating the artificial intelligence models.

In one or more embodiments, a system and method for optimizing a monitored system using artificial intelligence to detect optimization issues and automatically perform actions to correct them is provided. The system includes a processor that receives the current performance metrics that include information related to key performance indicators (KPIs) associated with a monitored system. The processor extracts a plurality of predetermined features from the current performance metrics and produces an optimization value by analyzing the extracted features using a trained artificial intelligence model that was trained using the historical performance metrics. When the optimization value is greater than a threshold, the processor analyzes the current performance metrics to identify specific optimization issues and determine an action to correct the specific issue. The processor then causes the monitored system to perform the action and stores the current performance metrics, the specific issue, and the action in a log.

In one or more embodiments, the disclosed system optimizes a monitored system. The system includes a processor that is operably coupled to a memory. The memory is configured to store current performance metrics, historical performance metrics, a trained artificial intelligence model, and a log. The processor periodically receives the current performance metrics related to key performance indicators (KPIs) associated with the monitored system and stores these in the memory. The processor then extracts a plurality of predetermined features from the current performance metrics, wherein each of the extracted plurality of predetermined features is associated with at least one of the KPIs associated with the monitored system. An optimization value is produced by analyzing the extracted plurality of predetermined features using the trained artificial intelligence model that was trained using the historical performance metrics. The optimization value indicates a probability that the current performance metrics indicate that the monitored system requires optimization.

When the optimization value is greater than a first threshold, in one or more embodiments, the processor takes several actions. It analyzes the current performance metrics to identify an issue of the monitored system that needs correcting to optimize the system. It then identifies one or more actions that are able to correct the issue. The processor then causes the monitored system to perform the action and stores the current performance metrics, the issue, and the action in the log. The processor may then update the trained artificial intelligence model using the current performance metrics as well as any feedback received from a user or administrator of the monitored system.

In one or more embodiments, the monitored system may comprise a plurality of computational units and/or one or more applications. The KPIs may be associated with specifics such as network latency and processor statistics; they may be associated with aspects of the applications or a combination thereof. The monitored system is monitored in real-time or near real-time using a trained unsupervised machine learning model or other trained artificial intelligence models.

The trained artificial intelligence models, in one or more embodiments, are produced by the processor performing a series of operations. The processor initially separates the historical performance metrics into a first set and a second set, with the first set being larger than the second set. The processor also selects an artificial intelligence algorithm based on the characteristics of the monitored system and trains the selected artificial intelligence algorithm to produce an intermediate model using a portion of the first set. The processor then validates the intermediate model using a second portion of the second set to produce a validation value, and when the validation value is greater than a second threshold, it saves the intermediate model in the memory as the trained artificial intelligence model. When the validation value is less than the second threshold, the processor retrains the intermediate model using a third portion of the first set to produce a retrained intermediate model and validates the retrained intermediate model using a fourth portion of the second set to produce a retrained validation value. The processor then saves the intermediate model in the memory as the trained artificial intelligence model when the retrained validation value is greater than the second threshold.

The disclosed system and method provide several practical applications, such as providing an efficient and up-to-date system for detecting optimization issues or other problems with applications and/or computing devices associated with the system. The system allows for the continuous and automatic detection of optimization issues using artificial intelligence that is able to understand and change as individual monitored systems and/or applications are changed and/or updated. The system is not specific to a particular application or computation device and, therefore, may perform automatic optimization and/or provide a common interface for a user or administrator to monitor the systems without a need to understand each constituent system or application. The automatic detection of optimization issues and automatic actions to correct the issues may be taken before a user or operator is even aware that a currently monitored component or system is becoming less efficient and/or slow. This allows for minor issues to be corrected before they become severe problems, compromise data, or cause noticeable slowing and/or system failures. Accordingly, the disclosed system alleviates technical issues present in complex distributed computing systems, where optimization issues are not easy to detect and correct. The system provides for better reliability, more efficient operation and energy use, less downtime, and fewer hardware failures. These technical advantages improve the reliability of an organization's computer and network systems.

Certain embodiments of the present disclosure may include some, all, or none of these advantages. These advantages and other features will be more clearly understood from the following drawings and claims.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 illustrates a diagram of an example system configured for using artificial intelligence to optimize a monitored system performing data processing in accordance with one or more embodiments;

FIG. 2 illustrates a flowchart of an example method for using artificial intelligence to optimize a monitored system; and

FIG. 3 illustrates a flowchart of an example method for selecting and training an artificial intelligence algorithm for optimizing a monitored system in accordance with one or more embodiments.

### DETAILED DESCRIPTION

Various embodiments will now be described more fully with reference to the accompanying drawings. The disclosure may, however, be embodied in many different forms and should not be construed as limited to the embodiments set forth herein.

Complex computing systems, such as but not limited to distributed computing systems, include multiple computing devices, servers, network connections, applications, and databases. During normal operation, as well as when upgrades are performed, complex computing systems routinely become less efficient as issues develop in components and aspects of those computing systems. Further, as demands for computations from one component or aspect of a monitored computing system increase, the entire monitored computing system may be negatively affected, resulting in a loss of optimization. Currently, there is no efficient system or application that is able to monitor all of the components of complex computing systems to identify optimization issues and correct them automatically before these become noticeable or significant problems.

In one or more embodiments, a processor is provided to monitor one or more monitored systems. The processor is configured to detect optimization issues in real-time or near real-time of one or more components, applications, databases, or storage of the monitored system. The processor also performs one or more actions to optimize the monitored systems. The processor has the capability to learn and adjust as new or upgraded components or applications are added to the system by leveraging artificial intelligence. The processor also provides information on detected issues and actions taken to correct the issues to users or administrators, allowing them to identify additional actions such as, but not limited to, purchasing additional computational devices, preparing new code, or other actions. The users or administrators are also able to provide feedback on the detection and actions performed. This feedback may then be used to re-train the artificial intelligence model.

### System for Detecting Optimization Issues and Performing Actions, Overview

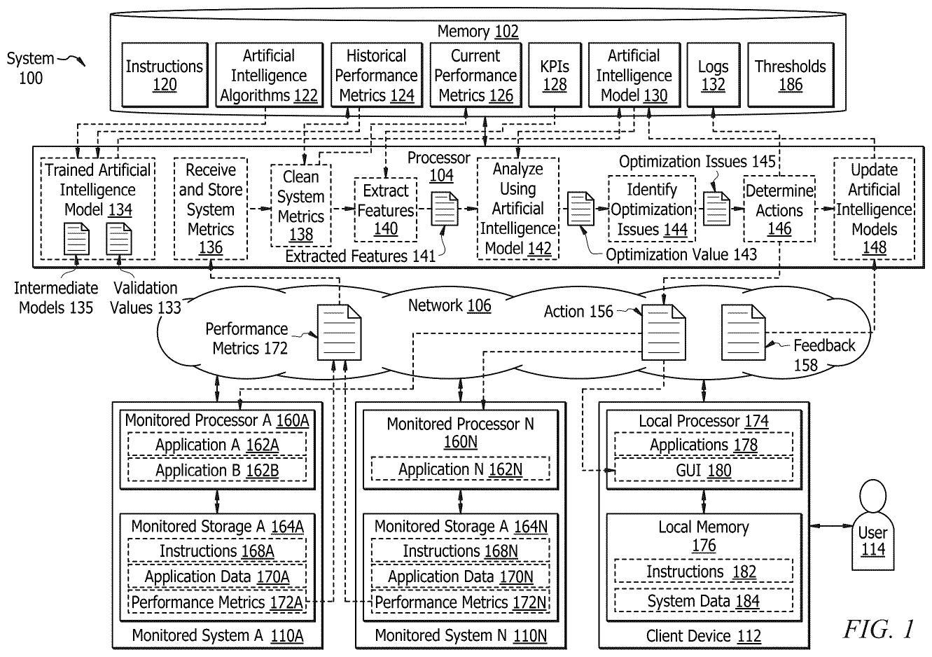

FIG. 1 is a schematic diagram of a system 100 configured for monitoring one or more monitored systems 110A-110N that host applications 162A-162N and application data 170A-170N. System 100 monitors performance metrics 172 for the monitored systems 110A-110N and utilizes one or more trained artificial intelligence models 130 to determine in real-time when optimization issues 145 are present in the monitored systems 110A-110N. The system then causes the monitored systems 110A-110N to perform one or more actions 156 to correct for the issues 145 and/or update a graphical user interface (GUI) 180 with information about the issues 145 and any actions 156 taken so a user 114 may provide feedback 158 or take additional actions 156 to correct the issues 145.

In one or more embodiments, system 100 comprises a plurality of monitored systems 110A-110N and a client device 112 that communicate with a processor 104 through a network 106. The processor 104 performs one or more operations based on instructions 120 stored in a memory 102, which is operably connected to the processor 104. The operations monitor for issues 145 and cause the monitored system 110A-110N to perform actions 156 to correct for detected issues 145. The system 100 may be configured as shown or in any other suitable configuration.

### Monitored System

In one or more embodiments, the system 100 includes at least one monitored system, e.g., 110A. The monitored systems 110A-110N may include multiple monitored processors 160A-160N, monitored storages 164A-164N, and may host a plurality of applications 162A-162N. While shown as a single device with a single monitored processor, e.g., 160A, each monitored system, e.g., 110A, may comprise multiple monitored processors 160A-160N and monitored storages 164A-164N that may be at a single location or data center or may be geographically dispersed. The applications 162A-162N may be hosted by one or more monitored processors 160A-160N, or some or all of the applications 162A-162N may be hosted on the cloud or other large computing systems. The disclosure is not limited to the specific configuration shown in FIG. 1, and the monitored systems 110A-110N may take any form without departing from the disclosure.

The monitored systems 110A-110N may be any number of devices hosting applications 162A-162N and/or application data 170A-170N. The monitored systems 110A-110N may include monitored storage 164A-164N and one or more monitored processors 160A-160N for performing operations, including but not limited to sending to the processor 104 through the network 106, performance metrics 172, and one or more applications 162A-162N. The monitored processor, e.g., 160A, may take the form of any electronic circuitry including, but not limited to, state machines, one or more central processing unit (CPU) chips, logic units, cores (e.g., a multi-core processor), field-programmable gate array (FPGAs), application specific integrated circuits (ASICs), or digital signal processors (DSPs).

The monitored processor, e.g., 160A, may be a programmable logic device, a microcontroller, a microprocessor, or any suitable combination of the preceding. The monitored processor, e.g., 160A, is communicatively coupled to and in signal communication with the monitored storage 164A-164N. One or more processors may make up each of the monitored processors 160A-160N and are configured to process data, which may be implemented in hardware or software. For example, the monitored processors 160A-160N may be 8-bit, 16-bit, 32-bit, 64-bit, or of any other suitable architecture. The monitored processors 160A-160N may include an arithmetic logic unit (ALU) for performing arithmetic and logic operations, processor registers that supply operands to the ALU and store the results of ALU operations, and a control unit that fetches instructions 168A-168N from the monitored storage 164A-164N and executes them by directing the coordinated operations of the ALU, registers and other components.

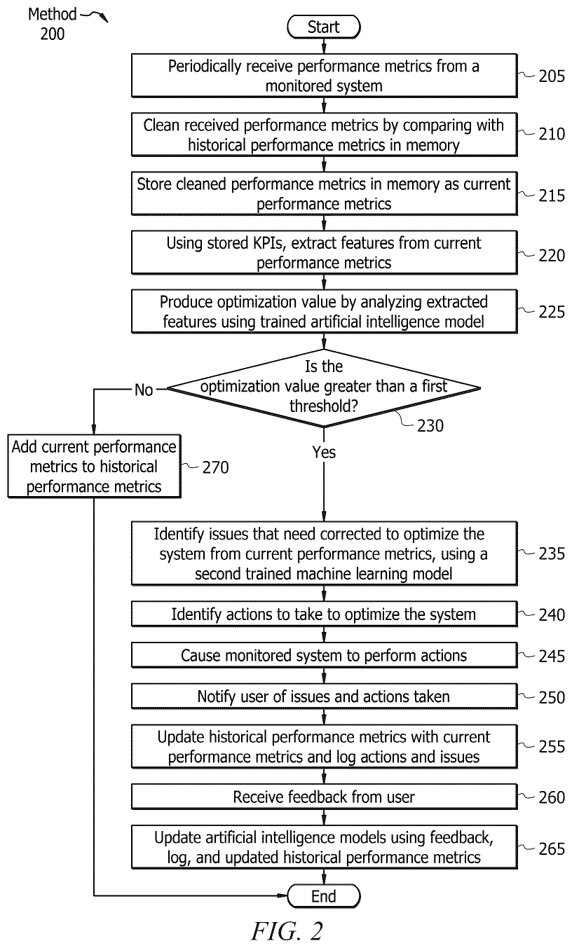

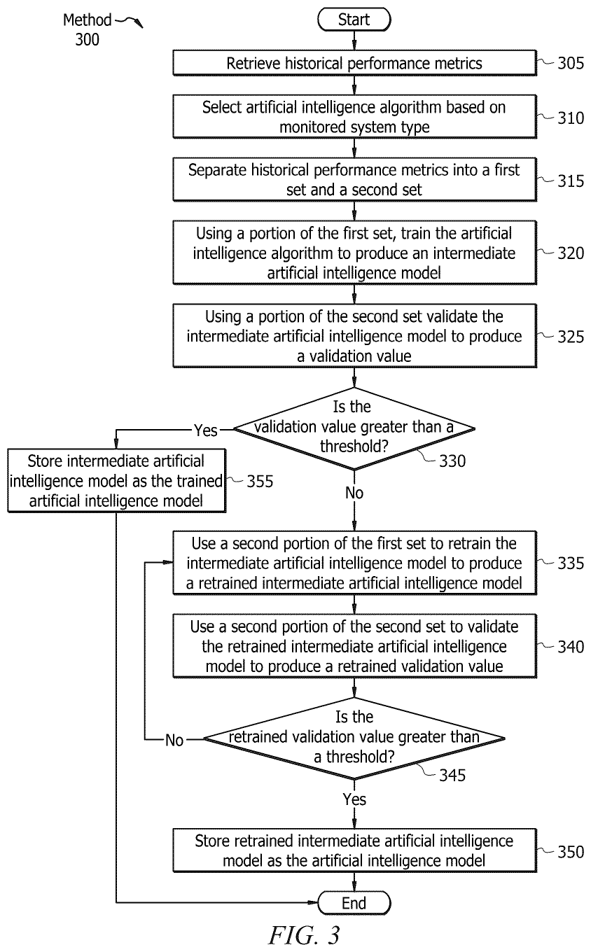

Each of the monitored processors 160A-160N is in operative communication with at least one monitored storage, e.g., 164A. A monitored processor, e.g., 160A, is configured to implement instructions 168A-16N stored in the monitored storages 164A-164N. The monitored processors 160A-160N may be a special-purpose computer designed to implement the instructions 168A-168N and/or functions disclosed herein. For example, the monitored processors 160A-160N may be configured to perform operations, including the operations of method 200 of FIG. 2 and method 300 of FIG. 3.

The monitored storage, e.g., 164A, may comprise a memory and/or maybe one or more disks, tape drives, or solid-state drives. Alternatively, or in addition, the monitored storage, e.g., 164A, maybe one or more cloud storage devices. The monitored storage, e.g., 164A, may be volatile or non-volatile. It may comprise read-only memory (ROM), random-access memory (RAM), ternary content-addressable memory (TCAM), dynamic random-access memory (DRAM), and static random-access memory (SRAM). The monitored storage, e.g., 164A, stores instructions, e.g., 168A, that, when executed by the monitored processor, e.g., 160A, causes the monitored processor, e.g., 160A, to perform the operations described below and in methods 200 and 300 of FIGS. 2 and 3. Instructions 168A-168N may comprise any suitable set of instructions, logic, rules, or code. The monitored storage, e.g., 164A, may include storage that may take the form of a database for storing such things as the application data 170A-170N. These may be stored and recalled using known protocols such as SQL, XML, and/or any other protocol or language that a user, administrator, or developer of the system 100 wishes to use. The application data 170A-170N may be stored in other forms, and the disclosure is not limited to storing application data 170A-170N as a database.

Each component of the monitored device, e.g., 110A, such as, but not limited to, the monitored processor, e.g., 160A, application, e.g., 162A, and application data, e.g., 170A, may develop optimization issues 145 over time as a result of day-to-day operations and/or upgrades and other activities to the component or connected/associated components. In one or more embodiments, the monitored processors 160A-160N gather operational data based on the physical status of the processor, e.g., 160A, monitored storage, e.g., 164A, applications, e.g., 162A, applications data, e.g., 170A and network 106 metrics associated with the functioning of the monitored systems 110A-110N. This operational data is stored in the monitored storage, e.g., 164A, as performance metrics, e.g., 172A.

In one or more embodiments, the stored performance metrics 172A-172N are periodically or continuously sent to the processor 104 and then analyzed by the processor 104 to detect optimization issues 145 and perform actions 156 on the monitored systems 110A-110N as will discussed in more detail below and with regards to the method 200 and method 300 of FIGS. 2 and 3 respectively. The performance metrics, e.g., 172A, may include information about the one or more monitored processors 160A-160N, such as but not limited to the processor's usage, thermal condition, processor type (e.g., graphical processing unit (GPU), and central processing unit (CPU)), speed, idle time, and any other information that is useful to detect optimization issues 145 in the behavior of the monitored processor, e.g., 160A and/or the applications 162A-162N that it hosts. The performance metrics, e.g., 172A, may also include information on the applications 162A-162N hosted by the monitored system, e.g., 110A, such as but not limited to, the specific version of an application, e.g., 162A, recent updates, application programming interface (API) information, other monitored systems, e.g., 110N that the application, e.g., 162A interacts with, specific performance metrics, e.g., 172A, for the application, and other key performance indicators (KPIs) 128 for the applications, e.g., 162A.

The performance metrics, e.g., 172A, may also include information related to the application data 170A-170N and the physically monitored storage 164A-164N that the application data 170A-170N resides on. For example, when the application data 170A is in the form of a database, the performance metrics, e.g., 172A, may include information on the type of database, level of data corruption, organization techniques, language supported by the database (e.g., SQL, XQuery, XML, OQL, etc.), and information gathered by the database's own monitoring systems. The performance metrics 172A may also include information on the storage devices that make up the monitored storage 164A-164N, this may include hard drive status, cloud storage status, and other useful information.

The performance metrics, e.g., 172A for a monitored system 110A, may also include other information such as connection and network information and any other information that is needed for detecting optimization issues 145 and monitoring the current performance and activity of the monitored system, e.g., 110A. While a specific example of information stored in the performance metrics 172A-172N is described above, the disclosure is not limited to those listed and may be any data related to the monitored system, e.g., 110A that is useful in detecting optimization issues 145 and performing actions 156 to correct for them.

### Client Device

In one or more embodiments, the system 100 may also include one or more optional client devices, e.g., 112. The client device 112 may take any form and, in general, is provided to allow a user 114, such as an administrator or other information technology (IT) professional, to monitor and make changes to system 100 and/or one or more monitored systems 110A-110N. In one or more embodiments, the client device 112 communicates with the processor 104 and the monitored systems 110A-110N through the network 106. Alternatively, the client device 112 may be part of one or more of the monitored systems, e.g., 110 and/or the processor 104.

Examples of the client devices 112 include, but are not limited to, computers, laptops, mobile devices (e.g., smartphones or tablets), servers, clients, or any other suitable type of devices that may host one or more applications 178 as well as a graphical user interface (GUI) 180. The client device 112 may include a local memory 176 and one or more local processors 174 for performing operations, including but not limited to performing applications 178 and a GUI 180 as well as sending to the processor 104 through the network 106, feedback 158 used by the processor 104 for updating the artificial intelligence model 130.

The local memory 176 may be one or more disks, tape drives, or solid-state drives. Alternatively, or in addition, the local memory 176 may be one or more cloud storage devices or a combination of local and cloud storage devices. The local memory 176 may be volatile or non-volatile. It may comprise read-only memory (ROM), random-access memory (RAM), ternary content-addressable memory (TCAM), dynamic random-access memory (DRAM), and static random-access memory (SRAM).

The local memory 176 stores instructions 182 that, when executed by the local processor 174, causes the local processor 174 to provide the user 114 with a graphical display that indicates such things, for example, as the current level of optimization, optimization values 143, optimization issues, 145, and automatic actions 156 that have been performed. The GUI 180 may display other useful information to the user 114 as well as allow the user 114 to interact with other applications 178 and the disclosed GUI 180 is not limited to displaying the information described and listed above. The user is able to see the optimization issues 145, extracted features 141, and any other useful information. This allows the user 114 to provide feedback 158 to the processor 104, which may use that feedback 158 to update or retrain the artificial intelligence models 130. The user 114 may also determine, based on the information displayed in the GUI 180, that one or more additional actions are to be taken by the user 114 or another IT professional; for example, in a non-limiting example, the user 114 may determine that one or more components of the monitored device, e.g., 110A need to be physically replaced, repaired, or their number increased.

The local memory 176 may store any suitable set of instructions 182, which may take the form of logic, rules, or code, as well as system data 184. The local memory 176 may include storage that may take the form of a database for storing such things as the system data 184, performance metrics 172, extracted features 141, or any other information that is useful for the GUI 180 and applications 178. These may be stored and recalled using known protocols such as SQL, XML, and/or any other protocol or language that a user, administrator, or developer of the system 100 wishes to use. The system data 184 and any other information stored in the local memory 176 may be stored in other forms, and the disclosure is not limited to storing the system data 184 and other information in a database.

### Network

The network 106 may be any suitable type of wireless and/or wired network including, but not limited to, all or a portion of the Internet, an intranet, a private network, a public network, a peer-to-peer network, the public switched telephone network, a cellular network, a local area network (LAN), a metropolitan area network (MAN), a wide area network (WAN), and a satellite network. The network 106 may be configured to support any suitable type of communication protocol as would be appreciated by one of ordinary skill in the art.

The network 106 may connect the processor 104 with the memory 102 as well as the monitored systems 110A-110N and client device 112. In one or more embodiments, different elements of system 100 may be at different geographic locations and connected through network 106. The network 106 may connect the components of system 100 through the Internet or other large networks or through a local network. While shown as a single network 106, the network 106 may comprise a plurality of components of any suitable networking equipment, including but not limited to routers and switches, that allow at least the monitored components 110A-110N and client device 112 to communicate with the processor 104 and memory 102. Network 106 is not limited to the configuration shown in FIG. 1, which is simply shown in this form for simplicity and explanatory purposes.

### Memory

Memory 102 may be any type of storage for storing a computer program comprising instructions 120, artificial intelligence algorithms 122, historical performance metrics 124, current performance metrics 126, KPIs 128, artificial intelligence models 130, log 132, and thresholds 186. The memory 102 may be a non-transitory computer-readable medium in operative communication with the processor 104. The memory 102 may be one or more disks, tape drives, or solid-state drives. Alternatively, or in addition, the memory 102 may be one or more cloud storage devices. The memory 102 may be volatile or non-volatile. It may comprise read-only memory (ROM), random-access memory (RAM), ternary content-addressable memory (TCAM), dynamic random-access memory (DRAM), and static random-access memory (SRAM).

The memory 102 stores instructions 120 that, when executed by the processor 104, causes the processor 104 to perform the operations described below and in methods 200 and 300 of FIGS. 2 and 3, respectively. Instructions 120 may comprise any suitable set of instructions, logic, rules, or code. Memory 102 may include storage that may take the form of a database for storing such things as KPIs 128, Logs 132, historical performance metrics 124, current performance metrics 126, artificial intelligence algorithms 122, and artificial intelligence models 130. These may be stored and recalled using known protocols such as SQL, XML, and/or any other protocol or language that a user, administrator, or developer of the system 100 wishes to use. The KPIs 128, logs 132, historical performance metrics 124, current performance metrics 126, artificial intelligence algorithms 122, and artificial intelligence models 130 may be stored in other forms, and the disclosure is not limited to storing the KPIs 128, logs 132, historical performance metrics 124, current performance metrics 126, artificial intelligence algorithms 122, and artificial intelligence models 130 as a database.

The memory 102 in one or more embodiments stores artificial intelligence algorithms 122 and artificial intelligence models 130. In one or more embodiments, the processor 104, when training the artificial intelligence models in operation 134, selects from the artificial intelligence algorithms 122 stored in memory one or more appropriate artificial intelligence algorithms 122 that are applicable to the specific monitored system 110A. The processor 104 then trains the selected artificial intelligence algorithms 122 to produce the artificial intelligence model 130 that is used by the processor 104 when performing the analysis using artificial intelligence models operation 142 and/or during the identify optimization issues operation 144. For example, in a non-limiting example, the processor 104 may select a trained unsupervised machine learning algorithm to produce a trained unsupervised machine learning model, which is then saved in the memory 102 as one of the artificial intelligence models 130. The artificial intelligence algorithms 122 may include any useful artificial intelligence algorithms 122, such as, but not limited to, trained unsupervised machine learning algorithms, trained supervised machine learning algorithms, linear regression, logistic regression, decision trees, super vector machines, random forest, naïve Bayes, gradient boosting, principal component analysis, k-means clustering, hierarchical clustering, Q-learning, DBscan, isolation forest, convolutional neural network (CNN), long short-term memory (LSTM) neural networks, generative artificial intelligence, and any other useful artificial intelligence algorithms.

The memory 102 in one or more embodiments stores key performance indicators (KPIs) 128. The KPIs may be specific to the particular monitored system, or they may be general KPIs that are applicable to any particular system. The KPIs may be specific to the hardware/computational devices that make up the monitored system, the applications 162A-162N, application data 170A-170N, or any other components of a monitored system, e.g., 110A. In one or more embodiments, the KPIs may be selected from and/or include one or more of the KPIs listed in Table 1 below. However, the KPIs 128 and disclosure are not limited to those listed in Table 1, and Table 1 only provides exemplary KPIs, and KPIs 128 stored in memory 102 may include more or less than those listed in Table 1 without departing from the disclosure.

TABLE 1

| | | Key Performance |
|---|---|---|
| Testing Level | Category | Indicators (KPIs) |
| Platform- | Baseline | Throughput (MB/s) |
| Level Testing | Performance | Latency (ms) |
| | Testing | CPU Utilization (%) |
| | | Memory Usage (%) |
| | | Disk I/O (MB/s) |
| | | Network Throughput (MBps) |
| | | Query Execution Time (ms) |
| Platform- | Scalability | Performance Degradation (%) |
| Level Testing | Testing | Response Time (ms) |
| | | Resource Consumption |
| | | TrendNumber of Nodes Scaled |
| | | Query Latency under Load (ms) |
| Platform- | End-to-End | Data Processing Time (ms) |
| Level Testing | Workflow | Workflow Completion Time (ms) |
| | Testing | Data Accuracy (%) |
| | | Error Rate (%) |
| | | Resource Utilization (%) |
| Application- | Data | Data Accuracy (%) |
| Level Testing | Validation | Mismatch Rate (%) |
| | Testing | Data Consistency Errors |
| | | Processing Time (ms) |
| Application- | Concurrency | Maximum Concurrent Users |
| Level Testing | Testing | Query Execution Time under Load (ms) |
| | | Response Time (ms) |
| | | CPU and Memory Usage (%) |
| Application- | Regression | Performance Difference between Versions (%) |
| Level Testing | Performance | Query Execution Time Variance (ms) |
| | Testing | Resource Utilization Change (%) |
| ETL Tool | Workflow | ETL Execution Time (ms) |
| Testing | and Pipeline | Data Throughput (MB/s) |
| | Testing | Success Rate (%) |
| | | Error Rate (%) |
| ETL Tool | Error | Error Detection Rate (%) |
| Testing | Handling | Failure Recovery Time (ms) |
| | Validation | Data Loss Rate (%) |
| BI Tool | Report | Data Consistency (%) |
| Testing | Accuracy | Query Execution Time (ms) |
| | Testing | Report Load Time (ms) |
| BI Tool | Dashboard | Response Time under Load (ms) |
| Testing | Load Testing | Maximum Supported Users |
| | | Resource Utilization (%) |
| Web | Functional | Pass/Fail Rate (%) |
| Application | Testing | Defect Detection Rate (%) |
| Testing | | Response Time (ms) |
| Web | Performance | Page Load Time (ms) |
| Application | Testing | Request Processing Time (ms) |
| Testing | | Error Rate (%) |
| IoT | Sensor Data | Data Ingestion Rate (events/sec) |
| Performance | Testing | Latency (ms) |
| Testing | | Packet Loss (%) |
| IoT | Event | Event Processing Time (ms) |
| Performance | Processing | Throughput (events/sec) |
| Testing | Testing | Latency (ms) |
| Edge | Processing | Processing Time (ms) |
| Computing | Performance | CPU Utilization (%) |
| Testing | Testing | Memory Consumption (%) |
| Edge | Data | Sync Latency (ms) |
| Computing | Synchronization | Data Consistency (%) |
| Testing | Testing | Failure Recovery Time (ms) |
| Operating | Stress Testing | Maximum Sustained Load (%) |
| System-Level | | System Crash Rate (%) |
| Testing | | Recovery Time (ms) |
| Hardware- | Baseline | Disk I/O (MB/s) |
| Level Testing | Performance | CPU Speed (GHz) |
| | Testing | Memory Bandwidth (MB/s) |
| | | Network Throughput (MBps) |
| Integration- | End-to-End | Integration Success Rate (%) |
| Level Testing | Workflow | Data Transfer Rate (MBps) |
| | Testing | Workflow Completion Time (ms) |
| Network- | Scalability | Network Throughput (MBps) |
| Level Testing | Testing | Packet Loss (%) |
| | | Latency (ms) |
| | | Connection Scalability (sessions/sec) |
| Data | Compliance | Security Audit Score (%) |
| Governance | Testing | Policy Adherence (%) |
| Testing | | Data Retention Success Rate (%) |
| Performance | Configuration | Performance Gain (%) |
| Optimization | Tuning | Query Execution Time Change (ms) |
| Testing | Testing | Resource Utilization Efficiency (%) |
| Data | Volume | Maximum Data Processed (TB) |
| Volume/Big | Threshold | Query Performance Degradation (%) |
| Data Testing | Testing | Processing Time (ms) |
| Latency | Real-Time | End-to-End Latency (ms) |
| Testing | Data Testing | Event Processing Time (ms) |
| | | Data Delivery Rate (events/sec) |
| Cross- | Cloud vs. | Performance Variance (%) |
| Platform | On-Premise | Cost Efficiency (%) |
| Compatibility | Testing | Deployment Time (ms) |
| Testing | | |
| AI/ML-Based | Model | Inference Latency (ms) |
| Tool Testing | Performance | Accuracy (%) |
| | Testing | Throughput (predictions/sec) |
| | | Model Size (MB) |
| AI/ML-Based | Training | Training Time (ms) |
| Tool Testing | Pipeline | GPU Utilization (%) |
| | Testing | Convergence Rate |
| | | Dataset Size Processed (GB) |
| Database | Query | Query Execution Time (ms) |
| Performance | Performance | Query Throughput (queries/sec) |
| Testing | Testing | Index Efficiency (%) |
| Database | Transaction | Transactions Per Second (TPS) |
| Performance | Processing | Commit Latency (ms) |
| Testing | Testing | Rollback Rate (%) |
| Database | Concurrency | Maximum Concurrent Queries |
| Performance | Testing | Query Response Time under Load (ms) |
| Testing | | Lock Wait Time (ms) |
| Database | Replication & | Replication Lag (ms) |
| Performance | Sharding | Data Distribution Efficiency (%) |
| Testing | Testing | Shard Rebalancing Time (ms) |
| Database | Backup & | Backup Time (ms) |
| Performance | Restore | Restore Time (ms) |
| Testing | Performance | Data Integrity Check (%) |
| NoSQL | Document | Query Execution Time (ms) |
| Database | Store | Indexing Efficiency (%) |
| Testing | Performance | Document Retrieval Rate (docs/sec) |
| NoSQL | Key-Value | Read Latency (ms) |
| Database | Store | Write Latency (ms) |
| Testing | Performance | Cache Hit Ratio (%) |
| NoSQL | Graph | Query Execution Time (ms) |
| Database | Database | Traversal Time (ms) |
| Testing | Performance | Node Degree Distribution (%) |
| Messaging | Producer- | Message Throughput (messages/sec) |
| Queue | Consumer | Processing Latency (ms) |
| Testing | Performance | Queue Depth Growth Rate (%) |
| Messaging | Fault | Message Loss Rate (%) |
| Queue | Tolerance | Recovery Time (ms) |
| Testing | Testing | Redelivery Rate (%) |
| Cloud | Auto-Scaling | Scale-Out Latency (ms) |
| Service | Performance | Scale-In Latency (ms) |
| Performance | | Cost Efficiency (%) |
| Testing | | |
| Cloud | Storage | IOPS (Input/Output Operations per Second) |
| Service | Performance | Read/Write Latency (ms) |
| Performance | | Data Transfer Rate (MBps) |
| Testing | | |
| Security | Authentication & | Login Response Time (ms) |
| Testing | Authorization | Access Control Efficiency (%) |
| | | Token Expiry Accuracy (%) |
| Security | Data | Encryption Processing Time (ms) |
| Testing | Encryption & | Data Leakage Rate (%) |
| | Protection | Compliance Adherence (%) |

Returning to the memory 102, the memory 102 in one or more embodiments stores historical performance metrics 124 and current performance metrics 126. The historical performance metrics 124 include current performance metrics 126 from the logs 132 and/or any other performance metrics 172 that have been previously received from the monitor systems 110A-110N. The historical performance metrics 124 are used in one or more embodiments to train the artificial intelligence algorithm 122 to produce the artificial intelligence models 130 by the processor 104 performing the trained artificial intelligence mode operation 134. Alternatively, the trained artificial intelligence model 130 may be obtained from an external device (not shown), client device 112, or any other source. The historical performance metrics 124 may also be used by the processor 104 to clean the current performance metrics 126, which, then, have features extracted from them in operation 140 and are analyzed by the processor 104 using artificial intelligence models 130 in operation 142 to detect optimization issues 145 in operation 144.

Both the current performance metrics 126 and historical performance metrics 124 include performance metrics 172 received from the monitored systems 110A-110N. These performance metrics 172 may be cleaned by the processor 104, performing the clean performance metrics operation 138. This may include comparing current performance metrics 126 to the historical performance metrics 124 in order to eliminate duplicate performance metrics 126 or irrelevant metrics. The current performance metrics 126 and historical performance metrics 124 may also be filtered based on the KPIs 128 stored in the memory 102, so only the data that is relevant to one or more particular KPIs 128 is stored in the current performance metrics 126 and historical performance metrics 124.

The historical performance metrics 124 and current performance metrics 126 may be stored in any form. In one or more embodiments, the historical performance metrics 124 and current performance metrics 126 are stored in the memory 102 in the form of one or more databases. However, the historical performance metrics 124 and current performance metrics 126 may be stored in the memory 102 in any form, and the disclosure is not limited to storing them as a database. Further, the historical performance metrics 124 and current performance metrics 126 may be received, cleaned, and stored using any method, and the disclosure is not limited to those described above and below as being performed by the processor 104.

The memory 102 in one or more embodiments also stores at least one log 132 and thresholds 186. The thresholds 186 may store any values, percentages, scores, or other values that are used by the processor 104 when training the artificial intelligence models in operation 134, analyzing using artificial intelligence models in operation 142, detecting optimization issues 145 in operation 144, and any other operations described herein and below with regards to method 200 and 300 of FIGS. 2 and 3. The logs 132 may be used by processor 104 for updating the artificial intelligence model 130 in operation 148 as well as providing a user 114 or administrator historical information on what actions 156 and optimization issues 145 have been detected. The logs 132 may include such things as the extract features 141 that indicated optimization issues 145, the actions 156 taken to mitigate the optimization issues 145, and any other information that is determined to be useful for updating the artificial intelligence models 130 in operation 148 and producing the GUI 180 for the user 114.

### Processor

The processor 104 may take the form of any electronic circuitry including, but not limited to, state machines, one or more central processing unit (CPU) chips, logic units, cores (e.g., a multi-core processor), field-programmable gate array (FPGAs), application specific integrated circuits (ASICs), or digital signal processors (DSPs). The processor 104 may be part of the client device 112 or a separate processor 104. The processor 104 may be located on a single computational device or server or may be distributed across multiple devices, data centers, and/or cloud devices.

The processor 104 may be a programmable logic device, a microcontroller, a microprocessor, or any suitable combination of the preceding. The processor 104 is communicatively coupled to and in signal communication with the memory 102. One or more processors make up the processor 104 and are configured to process data, which may be implemented in hardware or software. For example, the processor 104 may be 8-bit, 16-bit, 32-bit, 64-bit, or of any other suitable architecture. The processor 104 may include an arithmetic logic unit (ALU) for performing arithmetic and logic operations, processor registers that supply operands to the ALU and store the results of ALU operations, and a control unit that fetches instructions 120 from memory 102 and executes them by directing the coordinated operations of the ALU, registers and other components. The processor 104 may take any form, and the disclosure is not limited to those described above and below.

The processor 104 is in operative communication with the memory 102. The processor 104 is configured to implement instructions 120 stored in memory 102. The processor 104 may be a special-purpose computer designed to implement the instructions 120 and/or functions disclosed herein. For example, the processor 104 may be configured to perform operations, including the operations of the methods described in FIG. 2. While a single processor 104 is shown, the processor 104 may include a plurality of processors or computational devices. The operations, e.g., train artificial intelligence model operation 134, receive and store performance metrics operation 136, clean performance metrics operation 138, extract features operation 140, analyze using artificial intelligence model operation 142, identify optimization issues operation 144, determine actions operation 146, and update artificial intelligence models operation 148, are described herein as being performed by the processor 104 and may be performed by a separate processor 104 or software application executed on a single computational device, e.g., processor 104, or they may be located on separate servers, separate datacenters such as a cloud server, and/or the client device 112 or monitored systems 110A-110N.

The processor 104 uses the artificial intelligence algorithm 122 stored in the memory 102 to train one or more artificial intelligence models 130 in operation 134. The artificial intelligence models 130 are then saved to the memory 102 and used to analyze extracted features 141 in operation 142. The processor 104 receives performance metrics 172 from the monitored systems 110A-110N and identifies one or more optimization issues 145, causing one or more actions 156 to be performed to correct the detected optimization issues 145. The processor 104 performs a plurality of operations such as, but not limited to, a receive and store performance metrics operation 136, clean performance metrics operation 138, extract features operation 140, analyze using artificial intelligence model operation 142, identify optimization issues operation 144, determine actions operation 146, and update artificial intelligence models operation 148, as will be described in more detail below and with regards to methods 200 and 300 of FIGS. 2 and 3. The processor 104 may perform more or fewer operations than shown in FIG. 1 and described in method 200 of FIG. 2 and method 300 of FIG. 3; the specific operations shown are only examples.

In one or more embodiments, the processor 104 performs a receive and store performance metrics operation 136. When performing this operation, the processor 104 receives performance metrics 172 from each of the monitored systems 110A-110N. These performance metrics 172 may comprise one or more of the performance metrics 172A-172N stored in the monitored storage 164A-164N of the monitored systems 110A-110N. The receive and store performance metrics operation 136 is performed continuously, and the real-time or near real-time performance metrics 172 that are gathered are stored by the processor 104 in the memory 102 as current performance metrics 126. After the current performance metrics 126 have been analyzed, as will be described in more detail below and with regards to method 200 of FIG. 2, or as new performance metrics 172 are received, the current performance metrics 126 are moved and stored as historical performance metrics 124 in the memory 102. The current performance metrics 126 are the most recent set of performance metrics 172 received from the monitored systems 110A-110N, while the historical performance metrics 124 are those performance metrics 172 that are older than a predetermined amount of time, with the predetermined amount of time being stored in the memory 102 as a threshold 186, and may be any amount of time that is useful for detecting optimization issues 145 without the amount of stored dated becoming such that the processor 104 is unable to analyze it in real-time or near real-time.

In one or more embodiments, the historical performance metrics 124 are used to initially train the artificial intelligence model in operation 134. Alternatively, the trained artificial intelligence models 130 may be produced using other data, or the trained intelligence models 130 may be obtained from an external source (not shown) such as, but not limited to, a manufacture of the monitored systems 110A-110N, a code library, or other provider of trained artificial intelligence models 130 and/or artificial intelligence algorithms 122. For example, in a non-limiting example, a trained unsupervised machine learning model may be obtained from a developer of a database application that is commonly used by the organization. Other types of artificial intelligence models 130 may be trained or obtained from an external source, and the disclosure is not limited to specific artificial intelligence models 130, artificial intelligence algorithms 122, or methods, e.g., 300 for training the artificial intelligence algorithms 122.

When training the artificial intelligence model 130, the processor 104 performs a series of operations 134. In one or more embodiments, processor 104 initially separates the historical performance metrics 124 into a first set and a second set, with the first set being larger than the second set. The processor 104 then selects one or more artificial intelligence algorithms 122 based on the characteristics of the monitored system, e.g., 110A. The artificial intelligence algorithms 122, as described above, may take any form and may be obtained from any source without departing from the disclosure.

Once the artificial intelligence algorithm 122 is selected, the processor 104 then trains the selected artificial intelligence algorithm 122 to produce an intermediate model 135 using a portion of the first set. The processor 104 then validates the intermediate model 135 using a second portion of the second set to produce a validation value 133. When the validation value 133 is greater than a threshold 186 stored in memory 102, the processor 104 saves the intermediate model 135 in the memory 102 as the trained artificial intelligence model 130. When the validation value 133 is less than the threshold 186, the processor 104 retrains the intermediate model 135 using a third portion of the first set to produce a retrained intermediate model 135 and validates the retrained intermediate model 135 using a fourth portion of the second set to produce a retrained validation value 133. The processor 104 then saves the intermediate model 135 in the memory 102 as the trained artificial intelligence model 130 when the retrained validation value 133 is greater than the threshold 186.

The threshold 186 may be any value that is stored in the memory 102 for validating the intermediate artificial intelligence model 135. The threshold 186 is chosen based on criteria typically used in training artificial intelligence models, e.g., 130, as well as being a value that produces accurate optimization values 143 without requiring too much computational power and/or producing inaccurate results or false positives when operating in real-time or near real-time. In one or more embodiments, processor 104 repeats the steps of training the intermediate model 135 using portions of the first set and validating with portions of the second set until the validation value 133 is greater than the threshold 186.

The processor 104 may also update the artificial intelligence models 130 in operation 148 periodically or each time an action 156 is taken. When updating the artificial intelligence models 130 in operation 148, the operations taken in operation 134 are repeated using the current performance metrics 126 along with the historical performance metrics 124 and any feedback 158 received from the client device 112 and/or user 114.

Once the processor 104 completes training, the artificial intelligence model 130 in operation 134, or as the processor 104 receives and stores the performance metrics 172 in operation 136, the processor 104 in operation 138 cleans the performance metrics 172 received in operation 136 in operation 138. The processor 104 may compare the current performance metrics 126 to those in the historical performance metrics 124 to remove any data that is corrupt or determined not to be useful. In one or more embodiments, the processor 104, when cleaning the performance metrics 172 in operation 138, may use libraries, for example, those available with a selected programming language, like Python, that include libraries such as pandas to transform messy datasets into organized data with standardized data types, fewer missing values, and fewer extremes. When the processor 104 cleans the performance metrics 172 in operation 138, the processor may use any technique to clean the data, and the disclosure is not limited to those provided by any specific programming language or by any specific technique.

Once the performance metrics 172 are cleaned by the processor 104 in operation 138, the processor extracts the extracted features 141 from the performance metrics 172 in operation 140. The extracted features 141 are extracted based on the stored KPIs 128 that are relevant to the particular monitored system, e.g., 110A. As discussed above with regards to Table 1, the KPIs 128 may be directed to features of the underlying hardware, network 106, applications 162A-162N, or any other characteristics of the monitored systems 110A-110N. In one or more embodiments, the processor 104 may also or instead perform principal component analysis to produce the extracted features 141.

Once the processor 104 produces the extracted features 141, it then uses the artificial intelligence models 130 in operation 142 to analyze the extracted features 141 and determine an optimization value 143. The processor analyzes the extracted features 141 and produces an optimization value 143, which is a score or percentage indicating whether the artificial intelligence mode 130 indicates that the probability is high that the extracted features 141 indicate that an optimization issue 145 is present in a component, application, data, or other aspects of the monitored system, e.g., 110A.

The processor 104 compares the optimization value 143 with another threshold 186 stored in the memory 102. When this optimization value 143 is greater than the threshold 186, the processor 104 then analyzes the current performance metrics 126 to detect a specific optimization issue 145. In one or more embodiments, the threshold 186 may be chosen by a user 114, administrator, or other appropriate personnel based on the specific monitored system 110A, or a standard value may be used for the monitored systems 110A-110N. For example, in a non-limiting example, if a monitored system, e.g., 110A, is critical to an organization's operations or comprises application data 170A that is frequently accessed and needs to be obtained in a timely manner, the user 114 may choose a low threshold 186 such as but not limited to fifty percent to ensure that any optimization issues 145 that are present are not missed. In another example, if the monitored system, e.g., 110N, is an application, e.g., 162N, that is less critical, a higher percentage may be chosen, such as eighty percent, so that less computing time and/or user time is used in attempting to detect optimization issues 145 that may not be present in the monitored system, e.g., 110N. The specific thresholds 186 are provided as only examples, and the disclosure is not limited to fifty percent or eighty percent. Any threshold 186 may be used without departing from the disclosure.

When the optimization value 143 is greater than the threshold 186, the processor then identifies optimization issues 145 in operation 144. These optimization issues 145 may be such things as, but not limited to, problems with the monitored processor, e.g., 160A, insufficient or too much computing capacities or resources for supporting and/or performing applications 162A-162N efficiently, issues with one application, e.g., 162A communicating with a second application, e.g., 162B, or application data 170A that is becoming corrupted or is in the wrong format for a particular application, e.g., 162N. The optimization issues 145 may take any form, and these are just examples; the disclosure is not limited to any particular optimization issue 145 or a particular type of monitored system 110A-110N. The specific optimization issues 145, in one or more embodiments, may be determined using a second trained artificial intelligence model 130, such as, but not limited to, DBSCAN or isolation forest.

Once the optimization issues 145 are identified by the processor 104 in operation 144, the processor determines the appropriate actions 156 to perform automatically. These actions 156 may include quarantining a part of or an entire monitored system, e.g., 110A or application, e.g., 162A adding one or more processors, e.g., 160A or removing one or more processors, e.g., 160N to either increase or decrease computing capacity; duplication application data, e.g., 170A; or any other actions 156. Action 156 may instead or in addition, include starting up or restarting a component of the monitored system, e.g., 110A, such as an additional CPU or server, or the action 156 may include having the monitored system, e.g., 110A, perform an update on at least one application, e.g., 162A, when the application, e.g., 162A, is found to need an update or not be able to correctly communicate with other applications, e.g., 162B. The specific actions 156 are not limited to those discussed herein, and the disclosure is not limited to these actions 156.

In one or more embodiments, the action 156 may include providing information or a notification to a client device 112 that optimization issues 145 are present. This may include providing information so that a user 114 viewing the GUI 180 may understand the nature of the optimization issues 145 and/or actions 156 and provide appropriate feedback 158 or take actions 156 that the processor 104 and/or monitored systems 110A-110N are unable to perform automatically. The specific actions 156 and information displayed on GUI 180 may take any form, and the disclosure is not limited to those just described. Once the processor 104 determines the actions 156 in operation 146 and the actions 156 are performed by either the processor 104, monitored systems 110A-110N, client device 112, or user 114, the specific actions 156 taken and extracted features 141 are stored in the log 132 and/or used to update the artificial intelligence models 130 in operation 148.

Processor 104 may perform more or less of the operations described and shown in FIG. 1. Processor 104 may perform the operations in any form or sequence, including those described below-regarding method 200, shown in FIG. 2, and method 300, shown in FIG. 3.

### Method for Automatically Detecting and Correcting Optimization Issues

FIG. 2 is a flowchart of an embodiment of method 200 for monitoring a monitored system, e.g., 110A, detecting optimization issues 145, and performing one or more actions 156 to optimize the monitored system, e.g., 110A by the processor 104. The method 200 may be performed by the processor 104 executing instructions 120, which are stored in memory 102.

The method 200 begins at operation 205. In operation 205, the processor 104 periodically receives performance metrics 172 from a monitored system, e.g., 110A. The performance metrics 172 may be determined in real-time or may be based on performance metrics, e.g., 172A, that are stored over a predetermined amount of time by the monitored processor, e.g., 160A. The processor 104 in operation 205 may receive the performance metrics 172 at a set interval such as, but not limited to, every five seconds, thirty seconds, a minute, or other intervals, or the processor 104 may receive the performance metrics 172 continuously as they are produced by the monitored system 110A or whenever one or more of the performance metrics 172 is determined to have changed, by the monitored processor, e.g., 160A or the processor 104.

Once processor 104 receives the performance metrics 172 in operation 205, processor 104 in operation 210 cleans the received performance metrics 172 by comparing them with historical performance metrics 124, stored in memory 102. When cleaning the performance metrics 172 in operation 210, the processor 104 may compare the current performance metrics 126 to those in the historical performance metrics 124 to remove any data that is corrupt or determined not to be useful. In one or more embodiments, the processor 104, when cleaning the performance metrics 172 in operation 210, may also use algorithms or techniques that are stored in software and/or code libraries, for example, the Pandas library, to transform messy datasets into organized data with standardized data types, fewer missing values, and fewer extremes. When the processor 104 cleans the performance metrics 172 in operation 210, the processor 104 may use any technique to clean the data, and the disclosure is not limited to those provided by any specific programming language or by any specific technique.

After the processor 104 cleans the performance metrics 172 in operation 210, the processor 104 in operation 215 stores the cleaned performance metrics 172 in the memory 102 as current performance metrics 126. The processor 104 then uses stored KPIs 128 stored in the memory 102 to extract features 141 from the stored current performance metrics 126 in operation 220. The extracted features 141 are extracted based on the stored KPIs 128 that are relevant to the particular monitored system, e.g., 110A. As discussed above with regards to Table 1, the KPIs 128 may be directed to features of the underlying hardware, network 106, applications 162A-162N, or any other characteristics of the monitored systems 110A-110N.

Once the processor 104 produces the extracted features 141 in operation 220, it then uses one or more selected trained artificial intelligence models 130 in operation 225 to produce an optimization value 143 by analyzing the extracted features 141. The selected trained artificial intelligence models 130 may be produced by performing the operations in method 300 described below and shown in FIG. 3 or by any other method. The processor 104 analyzes the extracted features 141 and produces an optimization value 143, which is a score or percentage indicating whether the artificial intelligence model 130 indicates that the probability is high that the extracted features 141 indicate that an optimization issue 145 is present in a component, application, e.g., 162A, application data, e.g., 170A, or other aspects of the monitored system, e.g., 110A.

The processor 104 in operation 230 determines if the optimization value 143 found in operation 225 is greater than a first threshold 186 stored in memory 102. In one or more embodiments, the threshold 186 may be chosen by a user 114, administrator, or other appropriate personnel based on the specific monitored system 110A, or a standard value may be used for the monitored systems 110A-110N. For example, in a non-limiting example, if a monitored system, e.g., 110A, is critical to an organization's operations or comprises application data 170A that is frequently accessed by other monitored systems, e.g., 110N, the user 114 may choose a low threshold 186 such as but not limited to fifty percent to ensure that any optimization issues 145 that are present are not missed. In another example, if the monitored system, e.g., 110N, is an application, e.g., 162N, that is less critical, a higher percentage may be chosen, such as eighty percent, so that less computing time and/or user time is used in attempting to detect optimization issues 145 that may not be present in the monitored system, e.g., 110N. The specific thresholds 186 are provided as only examples, and the disclosure is not limited to fifty percent or eighty percent. Any threshold 186 may be used without departing from the disclosure.

When the optimization value 143 is greater than the threshold 186, the processor 104 then identifies optimization issues 145 from the current performance metrics 126 using a second trained artificial intelligence model 130 in operation 235. These optimization issues 145 may be such things as, but not limited to, too little or too much processing capacity, network 106 issues, applications, e.g., 162A that need to perform updates, and/or other issues 145 with the applications 162A-162N, applications data 170A-170N, monitored processor 160A-160N or combinations. The optimization issues 145 may take any form, and these are just examples; the disclosure is not limited to any particular optimization issue 145 or a particular type of monitored system 110A-110N. The specific optimization issues 145, in one or more embodiments, may be determined using a second trained artificial intelligence model 130, such as, but not limited to, DBSCAN or isolation forest. Alternatively, in one or more embodiments, the processor 104 may use a different technique or algorithm to identify the optimization issues 145 without using the second artificial intelligence model 130. Method 200 is not limited to using a second-trained artificial intelligence model 130 and may use any technique to identify the optimization issues 145.

Once the optimization issues 145 are determined in operation 235, the processor 104 identifies actions 156 to take to optimize the system by addressing the optimization issues 145 in operation 240 and cause the monitored system, e.g., 110A, to perform in operation 245. In one or more embodiments, these actions 156 are automatic actions 156 that the processor 104 may perform or cause the monitored processor, e.g., 160A, to perform. The specific actions 156 may be stored in a look-up table that the processor 104 may use to identify what actions 156 correspond to, which identified optimization issues 145. Alternatively, the specific actions 156 may be determined using an algorithm, a different trained artificial intelligence model 130, or any other technique for determining what actions 156 to perform.

In one or more embodiments, the actions 156 may take any form. For example, the actions 156 may include quarantining an application, e.g., 162A, or a monitored system, e.g., 110A. In another non-limiting example, the actions 156 may cause the monitored system to increase or decrease its computing capacity or alternatively reassign computing capacity to applications, e.g., 162A that needs more capacity from applications, e.g., 162B that needs less capacity. In yet another non-limiting example, the actions 156 cause the monitored system, e.g., 110A, to restart one or more components of it or another monitored system, e.g., 110N. The actions 156 may also include causing the monitored system 110A to perform an update on at least one application, e.g., 162A, when the application, e.g., 162A, is found to need an update or not be able to correctly communicate with other applications, e.g., 162B. The specific actions 156 are not limited to the above examples, and the actions 156 may take any form without departing from the disclosure.

The processor, in optional operation 250, then notifies the user 114 of the actions 156 that have been performed. This may be done through the GUI 180 of the client device 112 or other means, including but not limited to sending emails, SMS notifications, alarms, or any other method of notifying the user 114. The notification sent to the user 114 may include other information so that a user 114 viewing the GUI 180 may understand the nature of the optimization issues 145 and provide appropriate feedback 158 or take actions 156 that the processor 104 and/or monitored systems 110A-110N are unable to perform automatically.

Once the processor 104 causes the monitored system to perform actions 156 in operation 245 and notifies the user 114 of the optimization issues 145 and actions 156 taken in operation 250, the processor 104 updates the historical performance metrics 124 with the current performance metrics 126 and logs the actions 156 and optimization issues 145 in the log 132 in operation 255. If user 114 provides feedback 158, it is received by processor 104 in operation 260. The logged actions 156, updated historical performance metrics 124, and any feedback 158 are used to update the artificial intelligence models 130 in operation 265 and method 200 ends.

Returning to operation 230, if the processor 104 in operation 230 instead determines the optimization value 143 is less than the first threshold 186, the processor in operation 270 adds the current performance metrics 126 to the historical performance metrics 124, and the method 200 ends. Once either operation 265 or operation 270 is completed by processor 104, the method may end. While shown as ending after operations 265 or operation 270, method 200 may be performed continuously as new performance metrics are received from a monitored system in operation 205 and/or as the artificial intelligence models 130 are updated and/or trained, as will be described below with regards to method 300 of FIG. 3.

Modifications, additions, or omissions may be made to method 200, as depicted in FIG. 2. Method 200 may include more, fewer, or other operations. For example, operations may be performed in parallel or in any suitable order. While discussed as being performed by processor 104 monitoring performance metrics from a monitored system, e.g., 110A, processor 104 may monitor a system 110A that is operatively connected to the processor and/or located on the same or a co-located server. Any combination of processors, e.g., 104 and monitored systems 110A-110N, may perform one or more of the operations of method 200.

### Method for Selecting and Training an Artificial Intelligence Algorithm

FIG. 3 is a flowchart of an embodiment of method 300 for training one or more artificial intelligence algorithms 122 to produce the trained artificial intelligence model 130 for monitoring the monitored systems 110A-110N and detecting one or more optimization issues 145 by the processor 104. The processor 104 may perform method 300 by executing the instructions 120 stored in memory 102, and method 300 may be part of the train artificial intelligence model operation 134 as described above or may be a separate method, e.g., 300.

The method 300 begins at operation 305. In operation 305, the processor 104 retrieves historical performance metrics 124 from the memory 102. The historical performance metrics 124 may be performance metrics 172 received from one or more monitored systems 110A-110N, which have been previously analyzed by the processor 104 and/or a user 114. Alternatively, in one or more embodiments, the historical performance metrics 124 may be obtained from a library, database, or other exterior source, such as but not limited to a vendor, that has useful performance metrics based on KPIs 128 that may be used to train an artificial intelligence model 130 to provide optimization values 143, and/or detect optimization issues 145. The historical performance metrics 124 may take any form, and the disclosure is not limited to those previously described.

Once the processor 104 retrieves the historical performance metrics 124 in operation 305, the processor selects an artificial intelligence algorithm 122 based on the monitored system, e.g., 110A type. For example, in a non-limiting example, if the monitored system, e.g., 110A, is one or more servers, the artificial intelligence algorithm 122 may be selected in operation 310 based on its suitability to determine optimization issues 145 in a server. However, if the monitored system, e.g., 110A, is a database storing application data, e.g., 170A, the selected artificial intelligence algorithm 122 may be a different algorithm that is better at identifying optimization issues in databases.

Once the processor 104 selects an artificial intelligence algorithm 122 in operation 310, the processor 104 in operation 315 separates the historical performance metrics 124 into a first set and a second set, with the first set being larger than the second set. The size of the first and second sets may be determined based on the amount of data in the historical performance metrics 124, known amounts of data needed to accurately and efficiently perform training of a specific artificial intelligence algorithm 122. In one or more embodiments, the historical performance metrics 124 may be divided based on a set ratio or percentage such as, but not limited to, having the first set be seventy percent and the second set be thirty percent. Other ratios or percentages may be used, and these are merely examples. The method 300 and disclosure are not limited to a particular percentage or ratio.

Once the processor 104 separates the historical performance metrics in operation 315, the processor 104 in operation 320 uses a portion of the first set to train the selected artificial intelligence algorithm 122 to produce an intermediate artificial intelligence model 135 using a portion of the first set, and in operation 325 uses a second portion of the second set to produce a validation value 133. The processor 104 then determines in operation 330 if the validation value 133 is greater than a threshold 186. The threshold 186 may be any threshold value that is stored in the memory 102 for validating the intermediate artificial intelligence model 135. The threshold 186 is chosen based on criteria typically used in training artificial intelligence models 130 as well as being a value that produces accurate optimization values 143 without requiring too much computational power and/or producing inaccurate results or false positives when operating in real-time. In one or more embodiments, processor 104 repeats the steps of training the intermediate artificial intelligence model 135 using portions of the first set and validating with portions of the second set until the validation value 133 is greater than the threshold 186.

When the validation value 133 is less than the threshold 186, the processor 104 retrains the intermediate artificial intelligence model 135 in operation 335 by using a second portion of the first set to retrain the intermediate artificial intelligence model 135 to produce a retrained intermediate artificial intelligence model 135. The processor in operation 340 then uses a second portion of the second set to validate the retrained intermediate model 135 to produce a retrained validation value 133. Once the retrained validation value 133 is produced in operation 340, the processor 104 then determines if the retrained validation value 133 is greater than the threshold 186. If it is not, the processor 104 repeats operations 335-345 until a retrained intermediate artificial intelligence model 135 is produced with a retrained validation value 133 greater than the threshold 186.

Once the processor 104 determines that an intermediate artificial intelligence model 135 or retrained intermediate artificial intelligence model 135 in operation 330 or 345 is greater than the threshold 186, the processor either stores the initial intermediate artificial intelligence model 135 as the trained artificial intelligence model 130 in operation 355 or stores the retrained intermediate artificial intelligence model 135 as the artificial intelligence model 130 in operation 350. Once either operation 350 or 355 is completed by processor 104, the method may end. While shown as ending after operations 350 or 355, method 300 may be performed continuously as feedback 158, and new performance metrics 172 are added to the historical performance metrics 124. Modifications, additions, or omissions may be made to method 300, as depicted in FIG. 3. Method 300 may include more, fewer, or other operations. For example, operations may be performed in parallel or in any suitable order. While discussed as being performed by processor 104 monitoring performance metrics, e.g., 172A, from a monitored system, e.g., 110A, processor 104 may monitor a system 110A that is operatively connected to the processor and/or located on the same or a co-located server. Any combination of processors, e.g., 104 and monitored systems 110A-110N, may perform one or more of the operations of method 300.

While several embodiments have been provided in the present disclosure, it should be understood that the disclosed systems and methods might be embodied in many other specific forms without departing from the spirit or scope of the present disclosure. The present examples are to be considered illustrative and not restrictive, and the intention is not to be limited to the details given herein. For example, the various elements or components may be combined or integrated into another system, or certain features may be omitted or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

To aid the Patent Office and any readers of any patent issued on this application in interpreting the claims appended hereto, applicants note that they do not intend any of the appended claims to invoke 35 U.S.C. § 140(f) as it exists on the date of filing hereof unless the words “means for” or “operation for” are explicitly used in the particular claim.

1. A system comprising:
a memory configured to store current performance metrics, historical performance metrics, a trained artificial intelligence model, and a log; and
a processor operably coupled to the memory and configured to:
receive the current performance metrics from a monitored system, wherein the current performance metrics are received periodically and comprise information related to key performance indicators (KPIs) associated with the monitored system;
store the current performance metrics in the memory;
extract a plurality of predetermined features from the current performance metrics, wherein each of the extracted plurality of predetermined features is associated with at least one of the KPIs associated with the monitored system;
produce an optimization value by analyzing the extracted plurality of predetermined features using the trained artificial intelligence model that was trained using the historical performance metrics, wherein the optimization value indicates a probability that the current performance metrics indicate the monitored system requires optimization; and
when the optimization value is greater than a first threshold, the processor:
analyzes the current performance metrics to identify an issue of the monitored system that needs correcting to optimize the system;
identifies an action to correct the issue;
causes the monitored system to perform the action; and
stores the current performance metrics, the issue, and the action in the log.

2. The system of claim 1, further comprising updating the trained artificial intelligence model using the current performance metrics.

3. The system of claim 1, wherein the monitored system is a separate computing device, and the current performance metrics include network latency and processor statics.

4. The system of claim 1, wherein the monitored system includes an application, and the KPIs are associated with the application.

5. The system of claim 1, wherein analyzing the current performance metrics is performed in real-time using a trained unsupervised machine learning model.

6. The system of claim 5, wherein the trained artificial intelligence model uses an isolation forest algorithm.

7. The system of claim 1, wherein the processor produces the trained artificial intelligence model by:
separating the historical performance metrics into a first set and a second set, wherein the first set is larger than the second set;
selecting an artificial intelligence algorithm based on characteristics of the monitored system;
training the selected artificial intelligence algorithm to produce an intermediate model using a portion of the first set;
validating the intermediate model using a second portion of the second set to produce a validation value;
when the validation value is greater than a second threshold, save the intermediate model in the memory as the trained artificial intelligence model; and
when the validation value is less than the second threshold:
retrain the intermediate model using a third portion of the first set to produce a retrained intermediate model;
validate the retrained intermediate model using a fourth portion of the second set to produce a retrained validation value; and
when the retrained validation value is greater than the second threshold, save the intermediate model in the memory as the trained artificial intelligence model.

8. The system of claim 1, wherein the action includes causing the monitored system to increase computing capacity.

9. The system of claim 1, wherein the action includes restarting one or more components of the monitored system associated with the issue.

10. The system of claim 1, wherein the action includes performing an update on an application associated with the monitored system.

11. A method for optimizing a monitored system comprising:
receiving current performance metrics from the monitored system, wherein the current performance metrics are received periodically and comprise information related to key performance indicators (KPIs) associated with the monitored system;
storing the current performance metrics in a memory, wherein the memory is configured to store the current performance metrics, historical performance metrics, a trained artificial intelligence model, and a log;
extracting a plurality of predetermined features from the current performance metrics, wherein each of the extracted plurality of predetermined features is associated with at least one of the KPIs associated with the monitored system;
producing an optimization value by analyzing the extracted plurality of predetermined features using the trained artificial intelligence model that was trained using the historical performance metrics, wherein the optimization value indicates a probability that the current performance metrics indicate the monitored system requires optimization; and
when the optimization value is greater than a first threshold:
analyzing the current performance metrics to identify an issue of the monitored system that needs correcting to optimize the monitored system;
identifying an action to correct the issue;
causing the monitored system to perform the action; and
storing the current performance metrics, the issue, and the action in the log.

12. The method of claim 11, wherein the method further comprises updating the trained artificial intelligence model using the current performance metrics.

13. The method of claim 11, wherein the trained artificial intelligence model is produced by:
separating the historical performance metrics into a first set and a second set, wherein the first set is larger than the second set;
selecting an artificial intelligence algorithm based on characteristics of the monitored system;
training the selected artificial intelligence algorithm to produce an intermediate model using a portion of the first set;
validating the intermediate model using a second portion of the second set to produce a validation value;
when the validation value is greater than a second threshold, saving the intermediate model in the memory as the trained artificial intelligence model; and
when the validation value is less than the second threshold:
retraining the intermediate model using a third portion of the first set to produce a retrained intermediate model;
validating the retrained intermediate model using a fourth portion of the second set to produce a retrained validation value; and
when the retrained validation value is greater than the second threshold, saving the intermediate model in the memory as the trained artificial intelligence model.

14. The method of claim 11, wherein the action includes causing the monitored system to increase computing capacity.

15. The method of claim 11, wherein the action includes performing an update on an application associated with the monitored system.

16. A non-transitory computer-readable medium storing instructions that, when executed by a processor, cause the processor to:
receive current performance metrics from a monitored system, wherein the current performance metrics are received periodically and comprise information related to key performance indicators (KPIs) associated with the monitored system;
store the current performance metrics in a memory, wherein the memory is configured to store the current performance metrics, historical performance metrics, a trained artificial 10 intelligence model, and a log;
extract a plurality of predetermined features from the current performance metrics, wherein each of the extracted plurality of predetermined features is associated with at least one of the KPIs associated with the monitored system;
produce an optimization value by analyzing the extracted plurality of predetermined features using the trained artificial intelligence model that was trained using the historical performance metrics, wherein the optimization value indicates a probability that the current performance metrics indicate the monitored system requires optimization; and
when the optimization value is greater than a first threshold:
analyze the current performance metrics to identify an issue of the monitored system that needs correcting to optimize the monitored system;
identify an action to correct the issue;
cause the monitored system to perform the action; and
store the current performance metrics, the issue, and the action in the log.

17. The non-transitory computer-readable medium of claim 16, wherein the instructions further cause the processor to update the trained artificial intelligence model using the current performance metrics.

18. The non-transitory computer-readable medium of claim 16, wherein the trained artificial intelligence model is produced by:
separating the historical performance metrics into a first set and a second set, wherein the first set is larger than the second set;
selecting an artificial intelligence algorithm based on characteristics of the monitored system;
training the selected artificial intelligence algorithm to produce an intermediate model using a portion of the first set;
validating the intermediate model using a second portion of the second set to produce a validation value;
when the validation value is greater than a second threshold, saving the intermediate model in the memory as the trained artificial intelligence model; and
when the validation value is less than the second threshold:
retraining the intermediate model using a third portion of the first set to produce a retrained intermediate model;
validating the retrained intermediate model using a fourth portion of the second set to produce a retrained validation value; and
when the retrained validation value is greater than the second threshold, saving the intermediate model in the memory as the trained artificial intelligence model.

19. The non-transitory computer-readable medium of claim 16, wherein the action includes causing the monitored system to increase computing capacity.

20. The non-transitory computer-readable medium of claim 16, wherein the action includes performing an update on an application associated with the monitored system.
